(19) United States
(12) Patent Application Publication
(10) Pub. No.: US 2025/0256308 A1
(43) Pub. Date: Aug. 14, 2025

(54) SUBSTRATE CLEANING METHOD AND SUBSTRATE CLEANING APPARATUS

(71) Applicant: EBARA CORPORATION, Tokyo (JP)

(72) Inventors: NAOYUKI HANDA, Tokyo (JP); SATOMI HAMADA, Tokyo (JP); TOMOYA NISHI, Tokyo (JP)

(73) Assignee: EBARA CORPORATION, Tokyo (JP)

(21) Appl. No.: 19/193,991

(22) Filed: Apr. 30, 2025

Related U.S. Application Data
(63) Continuation of application No. 18/156,399, filed on Jan. 19, 2023, now abandoned.

(30) Foreign Application Priority Data
Jan. 21, 2022 (JP) 2022-007863

(51) Int. Cl. B08B 3/12; B01F 23/23; B01F 23/237; B01F 23/2373; B01F 101/24; B01F 101/58; B08B 1/10; B08B 1/32; B08B 3/02; B08B 3/08

(52) U.S. Cl. CPC B08B 3/12; B01F 23/2373; B01F 23/23764; B01F 23/23765; B01F 23/238; B08B 1/10; B08B 1/32; B08B 3/02; B08B 3/08; B01F 2101/24; B01F 2101/58

(57) ABSTRACT

A substrate cleaning method, including a step of transporting a substrate after the substrate has been polished; a step of holding the substrate substantially horizontally by a substrate holding portion; a step of scrub cleaning a lower surface of the substrate while rotating the substrate; a first step of, after the step of scrub cleaning is performed, supplying a chemical solution from a first nozzle to the lower surface of the substrate while rotating the substrate; and a second step of, after the first step is performed, supplying a bubble-containing pure water from a second nozzle to the lower surface of the substrate while rotating the substrate, wherein bubbles contained in the bubble-containing pure water have bubble diameters of 1 μm or more and 500 μm or less.

### CROSS-REFERENCE TO RELATED APPLICATION

This application is a continuation application of and claims the priority benefit of a prior application Ser. No. 18/156,399, filed on Jan. 19, 2023, which claims the priority benefits of Japanese application no. 2022-007863, filed on Jan. 21, 2022. The entity of the above-mentioned patent application is hereby incorporated by reference herein and made a part of this specification.

### BACKGROUND

### Technical Field

The disclosure relates to a substrate cleaning method and a substrate cleaning apparatus.

### Related Art

Patent Literature 1 (JP 2000-176386) discloses a substrate cleaning method in which an etchant is supplied to upper and lower surfaces of a held substrate to perform chemical cleaning, and then pure water is supplied to remove the etchant.

The disclosure provides a substrate cleaning method and a substrate cleaning apparatus having higher cleaning power.

### SUMMARY

According to one aspect of the disclosure, there is provided a substrate cleaning method, including a step of transporting a substrate after the substrate has been polished; a step of holding the substrate substantially horizontally by a substrate holding portion; a step of scrub cleaning a lower surface of the substrate while rotating the substrate; a first step of, after the step of scrub cleaning is performed, supplying a chemical solution from a first nozzle to the lower surface of the substrate while rotating the substrate; and a second step of, after the first step is performed, supplying a bubble-containing pure water from a second nozzle to the lower surface of the substrate while rotating the substrate, wherein bubbles contained in the bubble-containing pure water have bubble diameters of 1 μm or more and 500 μm or less.

According to another aspect of the disclosure, a substrate cleaning apparatus includes a transport unit configured to transport a substrate; a substrate holding portion configured to hold the substrate substantially horizontally and rotate the substrate; a first nozzle configured to supply a chemical solution to a lower surface of the substrate; a second nozzle configured to supply a bubble-containing pure water to the lower surface of the substrate; and a control unit configured to control the second nozzle to supply the bubble-containing pure water after the first nozzle supplies the chemical solution, wherein bubbles contained in the bubble-containing pure water have bubble diameters of 1 μm or more and 500 μm or less.

### BRIEF DESCRIPTION OF THE DRAWINGS

FIG. 1A is a diagram illustrating an example of a conventional substrate cleaning method.

FIG. 1B is a diagram illustrating an example of a conventional substrate cleaning method.

FIG. 2A is a diagram illustrating an overview of a substrate cleaning method according to one embodiment of the disclosure.

FIG. 2B is a diagram illustrating an overview of a substrate cleaning method according to one embodiment of the disclosure.

FIG. 2C is a diagram illustrating an overview of a substrate cleaning method according to one embodiment of the disclosure.

FIG. 3 is a schematic perspective diagram of a substrate cleaning apparatus according to one embodiment.

FIG. 4 is a schematic diagram showing an example of a pure water supply nozzle 5.

FIG. 5A is a schematic diagram showing another example of the pure water supply nozzle 5.

FIG. 5B is a schematic diagram showing yet another example of the pure water supply nozzle 5.

FIG. 6A is a schematic perspective diagram of a substrate cleaning apparatus according to another embodiment.

FIG. 6B is a schematic perspective diagram of a substrate cleaning apparatus according to yet another embodiment.

FIG. 7 is a process chart showing a procedure of substrate cleaning.

### DESCRIPTION OF THE EMBODIMENTS

It is desirable that a solution film of the chemical solution be formed on the lower surface of the substrate, and the solution film be replaced with the bubble-containing liquid by the second step.

It is desirable that a step of generating the bubble-containing liquid before the second step be provided.

It is desirable that in the step of generating the bubble-containing liquid, bubbles be generated in a cleaning liquid by ultrasonic waves so as to generate the bubble-containing liquid.

It is desirable that a supply flow rate of the bubble-containing liquid in the second step be higher than a supply flow rate of the chemical solution in the first step.

It is desirable that in the first step, the chemical solution be supplied from a first nozzle, and in the second step, the bubble-containing liquid be supplied from a second nozzle different from the first nozzle.

It is desirable that in the second step, the bubble-containing liquid be supplied from a single tube nozzle.

It is desirable that in the second step, the bubble-containing liquid be supplied to near a center of the lower surface of the substrate and to a peripheral portion of the substrate.

It is desirable that in the second step, the bubble-containing liquid and an ultrasonic cleaning liquid be supplied to the lower surface of the substrate.

It is desirable that in the second step, the bubble-containing liquid and two fluids be supplied to the lower surface of the substrate.

It is desirable that the bubble-containing liquid be pure water containing bubbles.

It is desirable that bubbles contained in the bubble-containing liquid have a diameter of 1 μm or more and 500 μm or less.

It is desirable that bubbles contained in the bubble-containing liquid be bubbles of one or more of nitrogen, hydrogen, ozone, carbon dioxide and oxygen.

It is desirable that a metal film be formed on an upper surface of the substrate, and bubbles contained in the bubble-containing liquid include bubbles of nitrogen or hydrogen, or include bubbles of nitrogen and hydrogen.

It is desirable that a step of scrub cleaning the lower surface of the substrate before the first step be provided.

It is desirable that in the first step, a chemical solution containing bubbles be supplied.

It is desirable that the second nozzle include: a gas supply unit; a liquid supply unit; a bubble-containing liquid generation unit that mixes a gas from the gas supply unit and a liquid from the liquid supply unit so as to generate the bubble-containing liquid; a housing in which the bubble-containing liquid generation unit is disposed; and a single tube nozzle that sprays the bubble-containing liquid generated to the lower surface of the substrate.

It is desirable that the second nozzle include: a gas supply unit; a liquid supply unit; a bubble-containing liquid generation unit that mixes a gas from the gas supply unit and a liquid from the liquid supply unit so as to generate the bubble-containing liquid; and a housing formed with a spray hole through which the bubble-containing liquid generated is sprayed.

It is desirable that an inclined surface extending obliquely downward from the spray hole be provided on an upper surface of the housing.

Cleaning power is improved.

Hereinafter, embodiments according to the disclosure will be specifically described with reference to the drawings.

The disclosure primarily relates to cleaning a lower surface of a substrate. First, an overview of the disclosure will be explained.

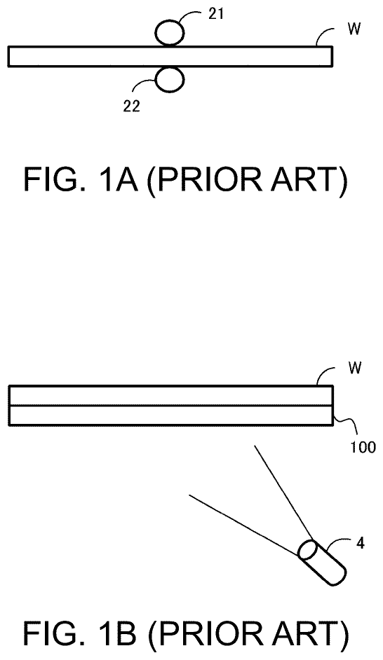

FIGS. 1A and 1B are diagrams illustrating an example of a conventional substrate cleaning method. First, an upper surface of a substrate W is scrub-cleaned with a roll sponge 21, and a lower surface of the substrate W is scrub-cleaned with a roll sponge 22 (FIG. 1A). The upper surface of the substrate W is the surface facing vertically upward in a held state (usually the surface on which devices are formed). Also, the lower surface of the substrate W is the surface facing vertically downward in the held state (usually the surface on which no devices are formed).

When scrub cleaning is completed, the roll sponges 21 and 22 are separated from the substrate W. Then, a chemical solution is supplied from a chemical solution supply nozzle 4 to the lower surface of the substrate W to perform chemical solution rinsing (FIG. 1B).

As illustrated, a solution film 100 of the chemical solution is formed on the lower surface of the substrate W by the supply of the chemical solution. This solution film 100 contains foreign substances and the like removed from the lower surface of the substrate W.

Next, pure water is supplied from a pure water supply nozzle (not shown) to the lower surface of the substrate W to perform pure water rinsing to remove the solution film 100.

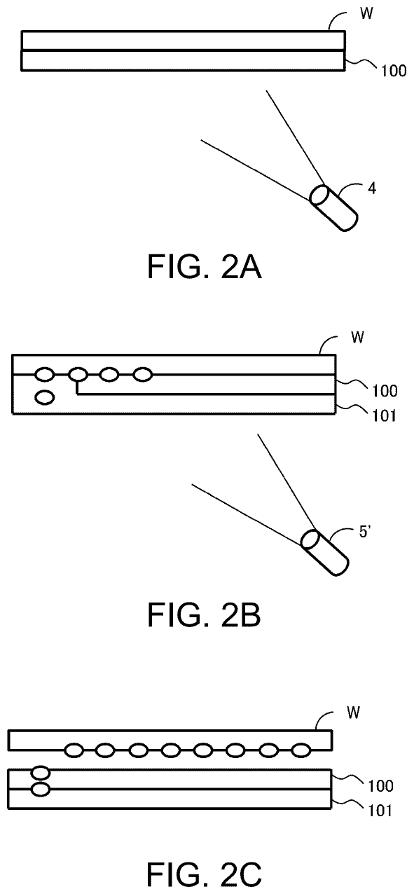

FIGS. 2A to 2C are diagrams illustrating an overview of a substrate cleaning method according to one embodiment of the disclosure. First, same as the conventional method, the upper surface and the lower surface of the substrate W are scrub-cleaned, and then the chemical solution is supplied to the lower surface of the substrate W to perform chemical solution rinsing, and the solution film 100 of the chemical solution is formed on the lower surface of the substrate W, and (FIG. 2A).

Next, pure water containing bubbles (hereinafter referred to as “bubble-containing pure water”) is supplied to the lower surface of the substrate W from a pure water supply nozzle 5. The bubbles in a bubble-containing pure water 101 that have reached the bottom of the solution film 100 of the chemical solution rise in the bubble-containing pure water 101 due to the buoyancy and enter a boundary between the lower surface of the substrate W and the solution film 100 (FIG. 2B). As a result, the solution film 100 is detached and dropped from the lower surface of the substrate W, and the solution film 100 is efficiently removed (FIG. 2C).

By supplying the bubble-containing pure water in this manner, the solution film 100 of the chemical solution is replaced with the bubbles, and remaining of the solution film 100 on the lower surface of the substrate W can be suppressed, thereby improving cleaning power.

A detailed description will be given below.

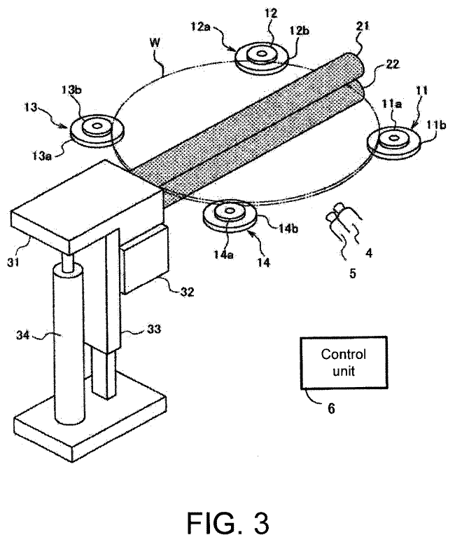

FIG. 3 is a schematic perspective diagram of a substrate cleaning apparatus according to one embodiment. The substrate cleaning apparatus includes four rollers 11 to 14 (substrate holding portions) disposed substantially on a same horizontal plane; two cylindrical roll sponges 21 and 22, which are cleaning units; rotation mechanisms 31 and 32 that rotate the roll sponges 21 and 22, respectively; the chemical solution supply nozzle 4; the pure water supply nozzle 5; and a control unit 6.

The roller 11 has a two-stage structure of a holding portion 11a and a shoulder portion (supporting portion) 11b. A diameter of the shoulder portion 11b is larger than a diameter of the holding portion 11a, and the holding portion 11a is provided on the shoulder portion 11b. The rollers 12 to 14 also have the same structure as the roller 11. The rollers 11 to 14 may be moved toward and away from each other by a drive mechanism (e.g. air cylinder) not shown. By bringing the rollers 11 to 14 close to each other, the holding portions 11a to 14a may hold the substrate W substantially horizontally. Moreover, at least one of the rollers 11 to 14 is configured to be rotationally driven by a rotation mechanism (not shown), thereby rotating the substrate W in the horizontal plane.

The roll sponge 21 extends in the horizontal plane, contacts the upper surface of the substrate W held by the rollers 11 to 14, and scrub-cleans it. The roll sponge 21 is rotated around the longitudinal direction of the roll sponge 21 by the rotation mechanism 31. Moreover, the rotation mechanism 31 is attached to a guide rail 33 that guides its vertical movement, and is supported by an elevation drive mechanism 34. The rotation mechanism 31 and the roll sponge 21 are vertically moved along the guide rail 33 by the elevation drive mechanism 34.

The roll sponge 22 extends in the horizontal plane, contacts the lower surface of the substrate W held by the rollers 11 to 14, and scrub-cleans it. The roll sponge 22 is disposed below the roll sponge 21 and rotated around the longitudinal direction of the roll sponge 22 by the rotation mechanism 32. Although illustration of an elevation drive mechanism and the like is omitted, the rotation mechanism 32 and the roll sponge 22 are also moved vertically in the same manner as the roll sponge 21.

The chemical solution supply nozzle 4 is positioned below (directly below or obliquely below) the substrate W and supplies the chemical solution to the lower surface of the substrate W.

The pure water supply nozzle 5 is positioned below (directly below or obliquely below) the substrate W and supplies the pure water to the lower surface of the substrate W. As one of the features of this embodiment, the pure water supply nozzle 5 supplies the bubble-containing pure water.

The control unit 6 controls the entire substrate cleaning apparatus. As one of the features of this embodiment, the control unit 6 controls the chemical solution supply nozzle 4 to supply the chemical solution, and then controls the pure water supply nozzle 5 to supply the bubble-containing pure water.

The following is a specific configuration example of the pure water supply nozzle 5.

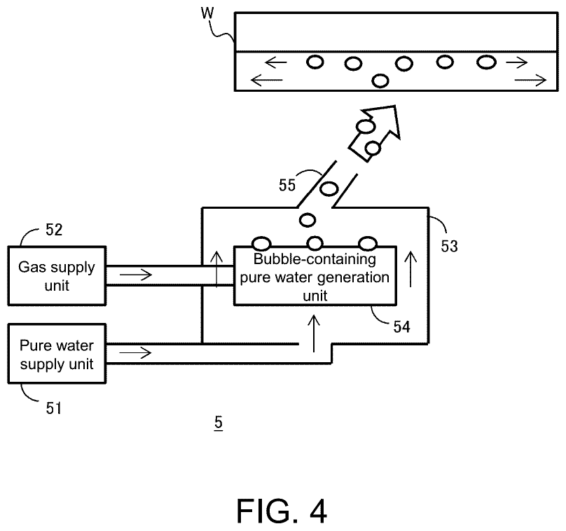

FIG. 4 is a schematic diagram showing an example of the pure water supply nozzle 5. The pure water supply nozzle 5 includes a pure water supply unit 51, a gas supply unit 52, a housing 53, a bubble-containing pure water generation unit 54, and a single tube nozzle 55. The pure water is supplied from the pure water supply unit 51 and a predetermined gas is supplied from the gas supply unit 52 to the bubble-containing pure water generation unit 54 disposed in the housing 53. Micropores are formed in the bubble-containing pure water generation unit 54, and the pure water and the gas are mixed to generate the bubble-containing pure water. The bubble-containing pure water generated is sprayed obliquely upward from the single tube nozzle 55 projecting from an upper surface of the housing 53. The sprayed bubble-containing pure water reaches near a center of the lower surface of the substrate W.

The pure water supply nozzle 5 may be fixedly disposed at a predetermined position, may be linearly movable, or may be swingable. In the case of swinging, it is desirable that the pure water supply nozzle 5 swing between a position where the bubble-containing pure water is sprayed near the center of the lower surface of the substrate W and a position where it is sprayed to a peripheral portion of the substrate W.

Further, an angle at which the bubble-containing pure water is supplied to the lower surface of the substrate W is not particularly limited. However, when the bubble-containing pure water is supplied only to the center of the lower surface of the substrate W, the bubble-containing pure water may not reach the peripheral portion of the substrate W. Therefore, two or more pure water supply nozzles 5 may be provided, one part of which supplies the bubble-containing pure water to near of the center of the lower surface of the substrate W, and the other part of which supplies the bubble-containing pure water to the peripheral portion of the lower surface of the substrate W.

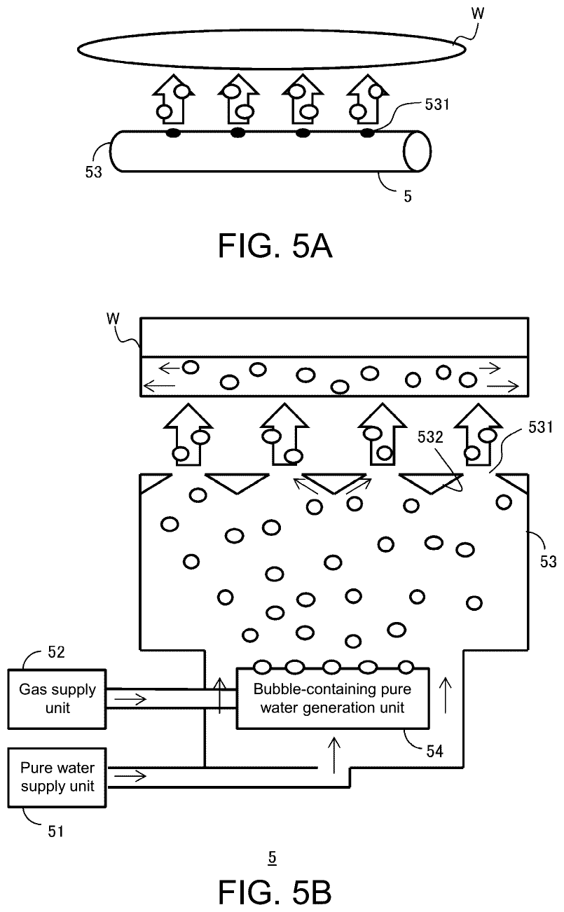

FIGS. 5A and 5B are schematic diagrams showing another example of the pure water supply nozzle 5 (FIG. 5A is a side view and FIG. 5B is a schematic cross-sectional view). The pure water supply nozzle 5 includes the pure water supply unit 51, the gas supply unit 52, the housing 53, and the bubble-containing pure water generation unit 54. The pure water is supplied from the pure water supply unit 51 and a predetermined gas is supplied from the gas supply unit 52 to the bubble-containing pure water generation unit 54 disposed in the cylindrical housing 53. Micropores are formed in the bubble-containing pure water generation unit 54, and the pure water and the gas are mixed to generate the bubble-containing pure water. The bubble-containing pure water generated is sprayed upward from one or a plurality of spray holes 531 formed in the upper surface of the housing 53. The sprayed bubble-containing pure water reaches the lower surface of the substrate W.

By providing the plurality of spray holes 531, the bubble-containing pure water may be sprayed over a wide region of the substrate W. It is desirable that a part of the spray holes 531 be disposed near and below the center of the lower surface of the substrate W, and another part be disposed below the peripheral portion of the lower surface of the substrate W.

Further, it is desirable that the upper surface of the housing 53 be devised such that bubbles do not accumulate. As an example, as shown, an inclined surface 532 extending obliquely downward from the spray hole 531 is provided. As a result, the bubbles rise along the inclined surface 532 and are guided to the spray holes 531 without accumulating on the upper surface of the housing 53.

Here, it is desirable that a diameter of the bubbles in the bubble-containing pure water be as large as possible within a range of not bursting, from the viewpoint of increasing the buoyancy of the bubbles. However, it is desirable that the diameter of the bubbles be smaller than the solution film of the chemical solution formed on the lower surface of the substrate W. To be specific, since a thickness of the solution film is about 200 to 500 μm, the diameter of the bubbles is preferably 1 μm or more and 500 μm or less, more preferably 100 μm or more and 500 μm or less. Further, it is desirable that a diameter of the single tube nozzle 55 in FIG. 4 or a diameter of the spray hole 531 in FIGS. 5A and 5B be larger than the diameter of the bubbles.

Moreover, it is desirable that a bubble density in the bubble-containing pure water be as high as possible, and particularly if a gas phase ratio is 80% or more, the cleaning effect will be enhanced.

The size and density of the bubbles may be adjusted, for example, by adjusting the size of the micropores of the bubble-containing pure water generation unit 54 shown in FIGS. 4 and 5B. Moreover, the bubble-containing pure water generation unit 54 may generate bubbles in the pure water by applying ultrasonic waves to the pure water, and the size and density of the bubbles may also be adjusted by the frequency of the ultrasonic waves.

In order to increase the buoyancy of the bubbles and efficiently remove the solution film of the chemical solution, it is desirable that a supply flow rate of the bubble-containing pure water be high to such an extent that the bubbles do not burst. To be specific, it is desirable that the supply flow rate of the bubble-containing pure water supplied from the pure water supply nozzle 5 be higher than a flow rate of the chemical solution supplied from the chemical solution supply nozzle 4.

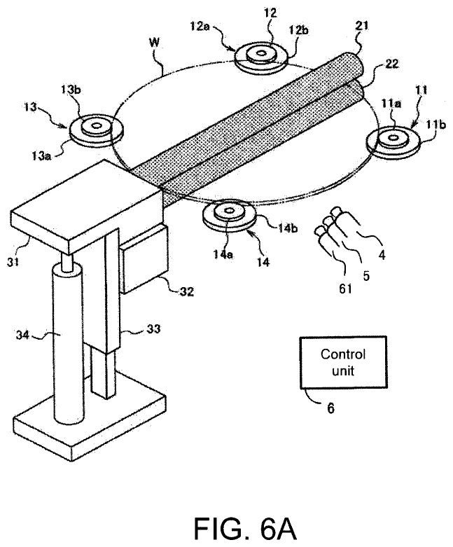

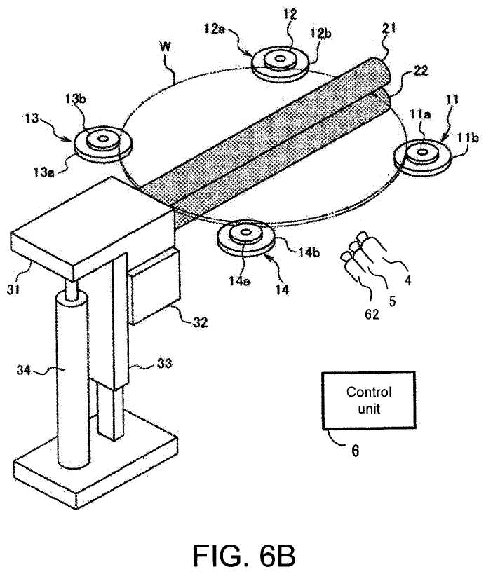

In addition to the chemical solution supply nozzle 4 and the pure water supply nozzle 5, an ultrasonic nozzle 61 that supplies an ultrasonic cleaning liquid to the lower surface of the substrate W may be provided (see FIG. 6A). Alternatively, in addition to the chemical solution supply nozzle 4 and the pure water supply nozzle 5, a two fluid jet nozzle 62 that supplies two fluids to the lower surface of the substrate W may be provided (see FIG. 6B). The two fluids are, for example, mixed fluids of liquid (e.g. pure water) and gas (e.g. nitrogen gas).

Moreover, the type of gas of the bubbles may be one of nitrogen, hydrogen, ozone, carbon dioxide and oxygen, or a mixture of two or more. That is, these gases may be supplied from the gas supply unit 52 of FIG. 4 or FIG. 5B.

When the bubbles contain nitrogen, the nitrogen bubbles reduce an amount of dissolved oxygen near the substrate W, and the nitrogen dissolved in the pure water suppresses the dissolved oxygen as functional water. As a result, corrosion (particularly oxidation) of metal film can be suppressed. Also, when the bubbles contain hydrogen, corrosion (particularly oxidation) of the metal film can be similarly suppressed, and re-adhesion of ceria abrasive grains (polishing liquid used for substrate polishing) can be suppressed. When the bubbles contain ozone, the substrate W can be made hydrophilic, and organic matter and inorganic matter adhering to the substrate W can be oxidized and eluted. When the bubbles contain carbon dioxide, charging of the substrate can be suppressed. By mixing a plurality of gas bubbles, each of the effects can be obtained.

Since the effect differs depending on the type of gas contained in the bubbles, it is desirable that the bubble-containing pure water containing bubbles with the type of gas corresponding to the substrate W as a cleaning object be supplied. For example, when a metal film such as a copper film is formed on the upper surface of the substrate, it is desirable that nitrogen or hydrogen be used to suppress oxidation.

Further, instead of pure water, other liquids containing bubbles may be supplied. The chemical solution supplied from the chemical solution supply nozzle may contain bubbles, thereby further improving the cleaning power.

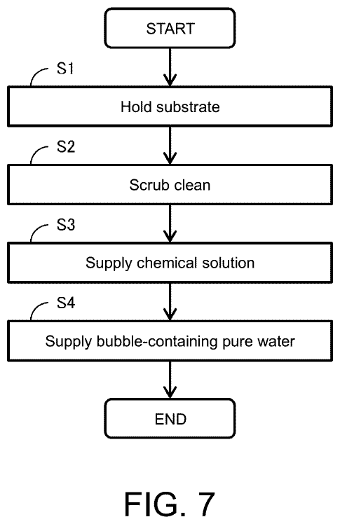

FIG. 7 is a process chart showing a procedure of substrate cleaning. Before cleaning the substrate W, that is, when the substrate W is loaded, the rollers 11 to 14 are separated from each other. Also, the roll sponge 21 is raised and the roll sponge 22 is lowered.

Then, in a state in which the roll sponges 21 and 22 are separated from a substrate holding position, the substrate W transported (for example, after being polished) by a transport unit (not shown) is placed on the shoulder portions 11b-14b of the rollers 11-14. After that, the rollers 11 to 14 move toward each other, that is, toward the substrate W, such that the substrate W is held substantially horizontally by the holding portions 11a to 14a. As a result, the substrate W is held substantially horizontally by the rollers 11 to 14 (step S1).

Note that when the substrate W as the cleaning object has been subjected to a polishing process, polishing waste and polishing liquid may adhere to the upper surface and the lower surface of the substrate W.

Next, the roll sponge 21 is lowered to contact the upper surface of the substrate W, and the roll sponge 22 is raised to contact the lower surface of the substrate W. Then, by having the substrate W is rotated in the horizontal plane by the rollers 11 to 14 and the roll sponges 21 and 22 rotating around their axes and come into contact with the upper and lower surfaces of the substrate W, respectively, the upper and lower surfaces of the substrate W are scrub-cleaned (step S2). When the scrub cleaning is completed, the roll sponge 21 is raised to separate from the upper surface of the substrate W, and the roll sponge 22 is lowered to separate from the lower surface of the substrate W.

Then, the chemical solution is supplied from the chemical solution supply nozzle 4 to the lower surface of the substrate W (step S3). In other words, the control unit 6 controls the chemical solution supply nozzle 4 to supply the chemical solution to the lower surface of the substrate W. As a result, the solution film of the chemical solution is formed on the lower surface of the substrate W, and chemical solution rinsing is performed on the lower surface of the substrate W.

After the chemical solution rinsing, the bubble-containing pure water is supplied from the pure water supply nozzle 5 to the lower surface of the substrate W (step S4). In other words, the control unit 6 controls the pure water supply nozzle 5 to supply the bubble-containing pure water to the lower surface of the substrate W. As a result, pure water rinsing is performed, as illustrated by FIGS. 2A to 2C, and (at least part of, preferably most of, more preferably all of) the solution film of the chemical solution formed on the lower surface of the substrate W is replaced with the bubble-containing pure water and removed from the lower surface of the substrate W.

Moreover, when the substrate cleaning apparatus includes the ultrasonic nozzle 61, the ultrasonic cleaning liquid may also be supplied in step S4. Also, when the substrate cleaning apparatus includes the two fluid jet nozzle 62, the two fluids may also be supplied in step S4.

As described, in this embodiment, in cleaning the lower surface of the substrate W, the bubble-containing pure water is supplied after the chemical solution rinsing. Therefore, the bubbles cause the solution film of the chemical solution to separate from the lower surface of the substrate W, and the remaining of the solution film on the lower surface of the substrate W is suppressed. As a result, cleaning power is improved.

Note that the method of generating bubbles is not limited to those exemplified in FIGS. 4, 5A, and 5B, and known methods may be used.

The above-described embodiments are described for the purpose of enabling a person having ordinary knowledge in the technical field to which the disclosure belongs to implement the disclosure. Various modifications of the above-described embodiments may be naturally made by those skilled in the art, and the technical idea of the disclosure may also be applied to other embodiments. Therefore, the disclosure should not be limited to the described embodiments, but should have the broadest scope in accordance with the spirit defined by the claims.

What is claimed is:

1. A substrate cleaning method, comprising:
a step of transporting a substrate after the substrate has been polished;
a step of holding the substrate substantially horizontally by a substrate holding portion;
a step of scrub cleaning a lower surface of the substrate while rotating the substrate;
a first step of, after the step of scrub cleaning is performed, supplying a chemical solution to the lower surface of the substrate while rotating the substrate; and
a second step of, after the first step is performed, supplying a bubble-containing pure water to the lower surface of the substrate while rotating the substrate,
wherein bubbles contained in the bubble-containing pure water have bubble diameters of 1 μm or more and 500 μm or less.

2. The substrate cleaning method according to claim 1,
wherein a solution film of the chemical solution is formed on the lower surface of the substrate by the first step, and
the solution film is replaced with the bubble-containing pure water by the second step.

3. The substrate cleaning method according to claim 1, wherein a supply flow rate of the bubble-containing pure water in the second step is higher than a supply flow rate of the chemical solution in the first step.

4. The substrate cleaning method according to claim 1,
wherein in the first step, the chemical solution is supplied from a first nozzle, and
in the second step, the bubble-containing pure water is supplied from a second nozzle different from the first nozzle.

5. The substrate cleaning method according to claim 1, wherein in the second step, the bubble-containing pure water is supplied from a single tube nozzle.

6. The substrate cleaning method according to claim 1, wherein in the second step, the bubble-containing pure water is supplied to near a center of the lower surface of the substrate and to a peripheral portion of the substrate.

7. The substrate cleaning method according to claim 1, wherein bubbles contained in the bubble-containing pure water are bubbles of one or more of nitrogen, hydrogen, ozone, carbon dioxide, and oxygen.

8. The substrate cleaning method according to claim 7,
wherein a metal film is formed on an upper surface of the substrate, and
bubbles contained in the bubble-containing pure water include bubbles of nitrogen or hydrogen, or include bubbles of nitrogen and hydrogen.

9. The substrate cleaning method according to claim 1,
wherein the chemical solution in the first step is alkaline or includes a surface active agent.

10. The substrate cleaning method according to claim 1, wherein in the first step, a chemical solution containing bubbles is supplied.

11. A substrate cleaning apparatus, comprising:
a transport unit configured to transport a substrate;
a substrate holding portion configured to hold the substrate substantially horizontally and rotate the substrate;
a first nozzle configured to supply a chemical solution to a lower surface of the substrate;
a second nozzle configured to supply a bubble-containing pure water to the lower surface of the substrate; and
a control unit configured to control the second nozzle to supply the bubble-containing pure water after the first nozzle supplies the chemical solution,
wherein bubbles contained in the bubble-containing pure water have bubble diameters of 1 μm or more and 500 μm or less.
